(19) United States
(12) Patent Application Publication
(10) Pub. No.: US 2025/0279289 A1
(43) Pub. Date: Sep. 4, 2025

(54) VAPORIZATION SYSTEM AND SEMICONDUCTOR PROCESS EQUIPMENT

(71) Applicant: BEIJING NAURA MICROELECTRONICS EQUIPMENT CO., LTD., Beijing (CN)

(72) Inventors: Zhishun YAN, Beijing (CN); Jianguo LI, Beijing (CN); Yang WANG, Beijing (CN); Miaomiao LI, Beijing (CN)

(21) Appl. No.: 18/859,025

(22) PCT Filed: Apr. 24, 2023
(86) PCT No.: PCT/CN2023/090198

§ 371 Date: Oct. 22, 2024

(30) Foreign Application Priority Data
Apr. 25, 2022 (CN) 202210442025.1

(51) Int. Cl. H01L 21/67

(52) U.S. Cl. CPC H01L 21/67017; H01L 21/67253

(57) ABSTRACT

The present disclosure provides a vaporization system and semiconductor process equipment. The vaporization system includes a jet mixer, a mixing heater, a process liquid source, and a plurality of pipelines. The process liquid source is configured to store and output process liquid. Two inlets of the jet mixer communicate with an external gas source and the process liquid source, respectively. The first inlet of the jet mixer communicates with the gas source through a gas inlet pipeline, and a second inlet of the jet mixer communicates with the process liquid source through the liquid inlet pipeline. The jet mixer is configured to mix the carrier gas transferred from the gas source with the process liquid transferred from the process liquid source to form a mist-like mixture. The inlet of the mixing heater communicates with the outlet of the jet mixer.

### TECHNICAL FIELD

The present disclosure generally relates to the semiconductor manufacturing field and, more particularly, to a vaporization system and semiconductor process equipment.

### BACKGROUND

In a boron diffusion process for a silicon wafer, an oxidation treatment needs to be performed on the silicon wafer before a boron diffusion reaction to form an oxide layer that is easy to remove or a tunneling oxide layer that enhances the boron diffusion effect. Moreover, the effect of the oxidation treatment influences the uniformity of the subsequent boron diffusion reaction. Currently, in the steps of the oxidation treatment, deionized water (DIW) steam is usually used to oxidize the silicon wafer. Thus, the vaporization level and flow rate of the deionized water steam have a significant impact on the effect of the oxidation treatment.

In traditional processes, a “bubbling method” is typically used to generate and transport the deionized water steam to a reaction chamber. As shown in FIG. 1, a traditional vaporization system comprises an inlet pipeline 01, a quartz bottle 02, a preheater 03, an outlet pipeline 04, and a purge pipeline 05. The quartz bottle 02 is configured to store deionized water, and the preheater 03 is configured to preheat the quartz bottle 02. Before starting to generate the steam, the inlet pipeline 01 is closed, and the outlet pipeline 04 and the purge pipeline 05 are open. Nitrogen gas is then introduced into the process chamber via the purge pipeline 05 to purge the pipelines and the process chamber. During the steam generation process, the purge pipeline 05 is closed, and the inlet pipeline 01 is opened. Then, nitrogen gas is introduced to carry the water vapor from the quartz bottle into the process chamber.

However, the actual flow rate of the deionized water steam output from the traditional vaporization system to the process chamber is difficult to control, which can reduce the uniformity of the oxidation treatment process to further affect the uniformity of the boron diffusion reaction within a single silicon wafer and the uniformity among a plurality of silicon wafers.

### SUMMARY

The present disclosure is intended to solve one of the technical problems in the existing technology and provides a vaporization system and semiconductor process equipment, which ensures process liquid is sufficiently vaporized and effectively controls a flow rate of generated steam.

To realize the present disclosure, a vaporization system is provided. The vaporization system is configured to transfer steam to a process chamber and comprises a jet mixer, a mixing heater, a process liquid source, a gas inlet pipeline, a liquid inlet pipeline, and a gas outlet pipeline.

The process liquid source is configured to store or output a process liquid.

A first inlet of the jet mixer is communicated with a gas source through the gas inlet pipeline, a second inlet of the jet mixer is communicated with a process liquid source through the liquid inlet pipeline, the jet mixer is configured to mix the carrier gas input from the gas source with the process liquid input from the process liquid source to form a mist-like mixture.

An inlet of the mixing heater is communicated with an outlet of the jet mixer, the mixing heater is configured to heat the mist-like mixture to vaporize the mist-like mixture into the steam, and an outlet of the mixing heater is communicated with the process chamber through the gas outlet pipeline.

In some embodiments, a gas flow rate controller is arranged on the gas inlet pipeline and is configured to control a flow rate of the carrier gas transferred to the jet mixer through the gas inlet pipeline, and a liquid flow rate controller is arranged on the liquid inlet pipeline and is configured to control a flow rate of the process liquid transferred to the jet mixer through the liquid inlet pipeline.

In some embodiments, a first on/off valve and a first check valve are further arranged on the gas inlet pipeline, the first on/off valve is located upstream of the gas flow rate controller and is configured to control the gas inlet pipeline to be on or off, and the first check valve is located downstream of the gas flow controller and is configured to prevent the mist-like mixture in the jet mixer from backflowing into the gas inlet pipeline.

A second on/off valve is further arranged on the liquid inlet pipeline, and the second on/off valve is located upstream of the liquid flow rate controller and is configured to control the liquid inlet pipeline to be on or off.

In some embodiments, a high-temperature flow rate controller is arranged on the gas outlet pipeline and is configured to control the flow rate of the steam transferred to the process chamber.

In some embodiments, the vaporization system further comprises a thermal insulation unit, and the thermal insulation unit is arranged on the gas outlet pipeline and the high-temperature flow rate controller and is configured to heat the gas outlet pipeline and the high-temperature flow rate controller.

In some embodiments, the process liquid source comprises a liquid source bottle and a preheater.

The liquid source bottle is configured to store the process liquid; and

The preheater is configured to heat the liquid source bottle so that the process liquid in the liquid source bottle is kept at a preset temperature.

In some embodiments, the vaporization system further comprises a pressurization pipeline, a gas inlet end of the pressurization pipeline communicating with the gas source, the gas outlet end of the pressurization pipeline communicating with the liquid source bottle, the inlet end of the liquid inlet pipeline communicating with the liquid source bottle, and the gas outlet end of the pressurization pipeline being higher than the inlet end of the liquid inlet pipeline.

The pressurization pipeline comprises a third on/off valve configured to control the pressurization pipeline to be on or off, and a second check valve located downstream of the third on/off valve and configured to prevent gas in the liquid source bottle from backflowing into the pressurization pipeline.

In some embodiments, the process liquid source further comprises a liquid level controller, a first liquid level sensor, a second liquid level sensor, and a liquid refilling pipeline.

The first liquid level sensor and the second liquid level sensor are arranged in the liquid source bottle and between a position of a gas outlet end of the pressurization pipeline and a position of an inlet end of the liquid inlet pipeline, the first liquid level sensor is arranged at a position higher than a position of the second liquid level sensor, the first liquid level sensor and the second liquid level sensor are configured to monitor a liquid surface height inside the liquid source bottle and send a detected liquid surface height value to the liquid level controller.

The liquid refilling pipeline is communicated with the liquid source bottle and is configured to transfer the process liquid to the liquid source bottle, and a fourth on/off valve is arranged on the liquid refilling pipeline and is configured to control the liquid refilling pipeline to be on or off.

The liquid level controller is configured to control the fourth on/off valve to be on or off according to the liquid surface height value sent by the first liquid level sensor and the second liquid level sensor.

In some embodiments, the pressurization pipeline further comprises a pressure detector configured to detect pressure inside the liquid source bottle.

The process liquid source further comprises a pressure-releasing pipeline communicating with the liquid source bottle or the pressurization pipeline, a fifth on/off valve being arranged on the pressure-releasing pipeline and configured to control the on/off of the pressure-releasing pipeline to be on or off according to a pressure value detected by the pressure detector. The present disclosure further provides semiconductor process equipment. The semiconductor process equipment comprises a process chamber and the vaporization system according to any one of claims 1 to 9. One or more process chambers are included, a number of the gas outlet pipelines is same as a number of process chambers, and outlet ends of the gas outlet pipelines communicate with the process chambers in a one-to-one correspondence.

The beneficial effects of the present disclosure are as follows.

The vaporization system of the present disclosure comprises a jet mixer, a liquid inlet pipeline configured to transfer the process liquid to the jet mixer, and the gas inlet pipeline configured to transfer the carrier gas to the jet mixer. The jet mixer is configured to mix the process liquid and the carrier gas transferred into the jet mixer to form the mist-like mixture. The vaporization system further comprises the mixing heater connected to the outlet of the jet mixer. The mixing heater is configured to heat the liquid transferred into the mixing heater to heat and vaporize the mist-like mixture into the steam to ensure that the process liquid output by the process liquid source is sufficiently vaporized. Thus, the amount of the process gas in the generated steam is the amount of the process liquid output by the liquid inlet pipeline. Then, the amount of the process gas participating in the process reaction in the process chamber can be controllable to further improve the efficiency and uniformity of the process.

In the semiconductor process equipment of the present disclosure, the vaporization system can be configured to transfer steam to one or more process chambers. Correspondingly, the vaporization system comprises gas outlet pipelines communicating with the process chambers in a one-to-one correspondence. Thus, one vaporization system can be configured to transfer the steam to one or more process chambers to improve the efficiency and uniformity of the process reaction in any of the process chambers.

### BRIEF DESCRIPTION OF THE DRAWINGS

FIG. 1 is a schematic structural diagram of an existing vaporization system.

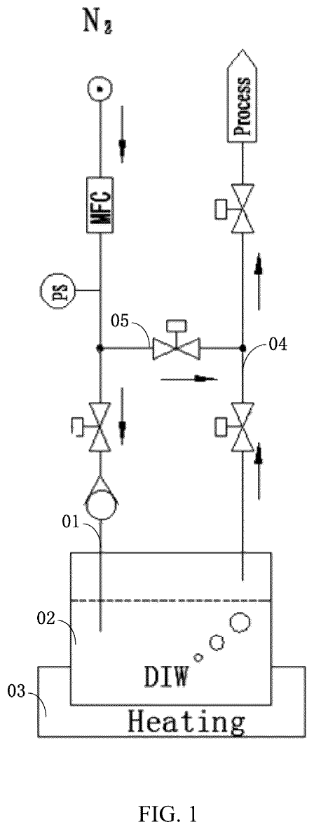

FIG. 2 is a schematic structural diagram of a vaporization system according to some embodiments of the present disclosure.

### DETAILED DESCRIPTION

To make those skilled in the art better understand the technical solutions of the present disclosure, a vaporization system and semiconductor process equipment of the present disclosure are described in detail below in connection with the accompanying drawings.

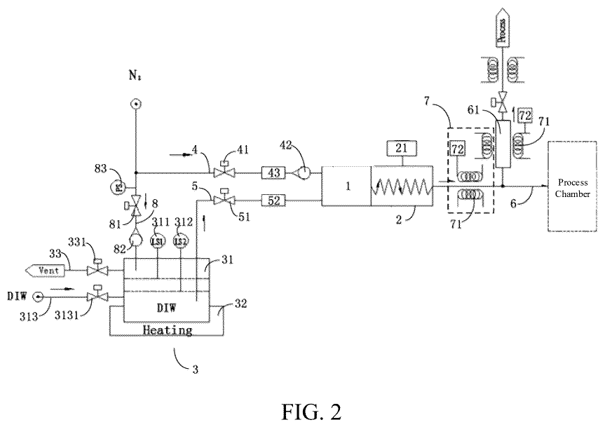

Embodiments of the present disclosure provide a vaporization system configured to transfer steam to a process chamber of semiconductor processing equipment. As shown in FIG. 2, the vaporization system comprises a jet mixer 1, a mixing heater 2, a process liquid source 3, and a plurality of pipelines (i.e., a gas inlet pipeline 4, a liquid inlet pipeline 5, and a gas outlet pipeline 6). The process liquid source 3 is configured to store and output process liquid. In some embodiments, the process liquid can include deionized water.

The first inlet of the jet mixer 1 is connected to an external gas source via the gas inlet pipeline 4. The external gas source can be configured to output a carrier gas. The carrier gas can include nitrogen or other inert gases. The second inlet of the jet mixer 1 is connected to the process liquid source 3 via the liquid inlet pipeline 5. The jet mixer 1 can be configured to mix the carrier gas from the gas source and the process liquid from the process liquid source 3 to form a mist-like mixture. In some embodiments, the mist-like mixture can be a combination of the carrier gas and the process liquid. The process liquid may not be fully vaporized but may exist in the form of fine droplets dispersed within the carrier gas.

The inlet of the mixing heater 2 is connected to the outlet of the jet mixer 1, and the outlet of the mixing heater 2 is communicated with the process chamber via the outlet pipeline 6. The mixing heater 2 can be configured to heat the mist-like mixture to sufficiently vaporize the mist-like mixture into steam. The steam can be output to the process chamber. In some embodiments, the mixing heater 2 can heat the mist-like mixture to the vaporization temperature of the process liquid to cause the fine droplets in the mist-like mixture to fully vaporize. Compared to directly heating the process liquid in a liquid state to vaporize, the process liquid in a fine droplet state can be more easily heated to vaporize. The time for the vaporization process can be shorter, and the power consumption can be lower. Thus, the process liquid can be fully vaporized more easily.

The steam transferred by the vaporization system of embodiments of the present disclosure to the process chamber can include process liquid steam and carrier gas. Since the process liquid is sufficiently vaporized, the amount of the process liquid steam transferred to the process chamber can be the amount of the process liquid output by the process liquid source to the jet mixer. That is, the output amount of the process liquid can be adjusted to adjust the amount of the process liquid steam in the steam transferred to the process chamber. Thus, the amount of the process liquid steam involved in the process reaction in the process chamber can be controllable to further improve the efficiency and uniformity of the process.

It should be noted that since the process liquid, steam, and mist-like mixture can belong to three different states, such as liquid, gas, and gas-liquid mixture, respectively. To quantize the process liquid, the steam, and the mist-like mixture, “amount” and “content” in the present disclosure can refer to the amount of a substance.

The inventors have discovered that the traditional vaporization method typically comprises introducing a carrier gas into a quartz bottle containing a process liquid. Thus, the carrier gas can carry the mist-like mixture into the process chamber. Therefore, the actual flow rate of the mist-like mixture can be difficult to measure. Since the carrier gas that is introduced can have a certain pressure and flow rate, it is difficult for the carrier gas to be sufficiently mixed with the process liquid in the quartz bottle. Thus, the vaporization system of embodiments of the present disclosure can include the jet mixer 1 and a mixing heater 2. Therefore, the carrier gas and the process liquid can be mixed in the jet mixer 1 to form a mist-like mixture. Then, the mixing heater 2 can be configured to cause the mist-like mixture to fully be vaporized to easily detect and control the process liquid flow rate and the carrier gas flow rate, which forms the steam. Thus, the steam output to the process chamber can satisfy the process requirement, and the efficiency and uniformity can be improved in the process chamber.

In some embodiments, the jet mixer 1 of embodiments of the present disclosure can be equipment configured to mix two or more liquids or gases. A typical jet mixer usually comprises a suction nozzle, a liquid nozzle, a mixing chamber, and a diffuser. The inlet of the suction nozzle can be used as the first inlet, and the outlet of the suction nozzle can face the inner part of the mixing chamber. The inlet of the liquid nozzle can be used as the second inlet. The outlet of the liquid nozzle can face the inner part of the mixing chamber. When the process liquid is ejected into the mixing chamber, since the process liquid has a certain flow rate, the carrier gas can be carried into the mixing chamber. Since the process liquid and the carrier gas have a speed difference, the carrier gas can disperse the process liquid. Thus, the process liquid and the carrier gas can be sufficiently mixed due to a mixing effect. After being mixed, the process liquid and the carrier gas can enter the diffuser. The inner radius of the diffuser can gradually enlarge. Thus, the overall volume of the liquid inside the diffuser can gradually increase as the liquid flows. Correspondingly, the inner pressure of the liquid can gradually reduce to cause the process liquid to be fully dispersed as a plurality of fine droplets. The fine droplets can further be mixed with the carrier gas to form the above mist-like mixture.

In some embodiments, the mixing heater 2 can be a heater, which is configured to directly heat a gas-liquid mixture, and include a heating channel. Two ends of the heating channel are communicated with the outlet of the jet mixer 1 and the inlet of the gas outlet pipeline 6. As shown in FIG. 2, the heating temperature of the mixing heater 2 is controlled by a temperature controller 21 of the mixing heater 2. In some embodiments, when the process liquid is deionized water, the heating temperature of the mixing heater 2 can be controlled at around 110° C. Thus, when the mist-like mixture passes through the heating channel inside the mixing heater 2, the fine droplets in the mist-like mixture can be quickly vaporized to ensure that the mist-like mixture is completely vaporized to improve the processing speed in the process chamber.

Thus, with the jet mixer and the mixing heater applied in the vaporization system of embodiments of the present disclosure, and thus, the process liquid can be sufficiently vaporized.

In some embodiments, a gas flow rate controller (43) is arranged on the gas inlet pipeline 4 and is configured to control the gas flow rate of the carrier gas transferred to the jet mixer 1 in the gas inlet pipeline 4. The gas flow rate controller 43 can adjust the actual gas flow rate inside the gas inlet pipeline 4 to the predetermined gas flow rate according to the detected gas flow rate. A liquid flow rate controller 52 is arranged on the liquid inlet pipeline 5 and is configured to control the liquid flow rate of the process liquid transferred to the jet mixer 1 in the liquid inlet pipeline 5. The liquid flow rate controller 52 can be further configured to adjust the actual liquid flow rate to the predetermined liquid flow rate inside the liquid inlet pipeline 5. In some embodiments, the predetermined gas flow rate, the predetermined liquid flow rate, and the ratio between the predetermined gas flow rate and the predetermined liquid flow rate can be adjusted according to the expected steam flow rate and ratio, e.g., the predetermined gas flow can be 30 l/min, and the predetermined liquid flow rate can be 2 g/min.

In some embodiments, a first on/off valve 41 and a first check valve 42 can be arranged on the gas inlet pipeline 4. The first on/off valve 41 can be arranged upstream of the gas flow rate controller 43 and can be configured to control the gas inlet pipeline 4 to be on/off. The first check valve 42 can be arranged downstream of the gas flow rate controller 43 and can be configured to prevent the mist-like mixture in the jet mixer 1 from returning to the gas inlet pipeline 4. The second on/off valve 51 can be arranged upstream of the liquid flow rate controller 52 and can be configured to control the liquid inlet channel 5 to be on/off.

In some embodiments, a gas outlet pipeline 6 can include a high-temperature flow rate controller 61, which can be configured to detect and control the flow rate of the steam in the gas outlet pipeline 6 under the high temperature to control the flow rate of the steam transferred to the process chamber. Although the gas flow rate controller 43 and the liquid flow rate controller 52 can detect and control the process liquid flow rate and the carrier gas flow rate forming the mis-like mixture, respectively. However, under the effect of the inner chamber of the jet mixer 1, the internal channel of the mixing heater 2, and the internal structure of the pipeline, the gas flow rate controller 43 and the liquid flow rate controller 52 can be configured to perform indirect detection and indirect control on the flow rate of the steam transferred to the process chamber, which introduces an error. In contrast, the high-temperature flow controller 61 can directly detect and control the flow rate of the steam. Thus, the detection and control of the flow rate of the steam transferred to the process chamber can be more accurate. Thus, the steam flow rate that is actually transferred into the process chamber can be more accurate.

In some embodiments, the vaporization system can further include a thermal insulation unit 7. The thermal insulation unit 7 can be arranged on the gas outlet pipeline 6 and the high-temperature flow rate controller 61 and can be configured to heat the gas outlet pipeline 6 and the high-temperature flow rate controller 61 to prevent the steam from liquefying within the gas outlet pipeline 6 and the high-temperature flow rate controller 61 and avoid damages due to excessive temperature difference between inside and outside of the high-temperature flow rate controller 61.

In some embodiments, the thermal insulation unit 7 can include a heating belt 71. The heating belt 71 can be arranged around the outer surface of the gas outlet pipeline 6 and can be configured to heat the outer wall of the gas outlet pipeline 6. In some embodiments, when the process liquid is deionized water, the preset heating temperature of the heating belt 71 can be at least 100° C. to ensure that the internal temperature of the gas outlet pipeline 6 is always equal to or higher than the vaporization temperature of deionized water to prevent the mist-like mixture from liquefying inside the gas outlet pipeline 6. In some embodiments, the thermal insulation unit 7 can also include a temperature controller 72, which can be configured to control the heating temperature of the heating belt 71. In some embodiments, the preset heating temperature of the heating belt 71 can be pre-stored in the temperature controller 72 or manually adjusted by staff before the process begins, or an external master control equipment can send a temperature adjustment signal to control the temperature controller 72.

In some embodiments, the process liquid source 3 can include a liquid source bottle 31 and a preheater 32. The liquid source bottle 31 can be configured to contain the process liquid. In some embodiments, the liquid source bottle 31 can be a steel bottle with good heat and pressure resistance. The preheater 32 can be configured to heat the liquid source bottle 31 to cause the process liquid inside the liquid source bottle 31 to maintain the preset temperature. In some embodiments, as shown in FIG. 2, the liquid source bottle 31 is arranged on the preheater 32 to pre-heat the process liquid source 3 in the liquid source bottle 31, which prevents the reduction in the mixing effect of the process liquid and the carrier gas in the jet mixer 1 due to excessive low process liquid temperature. In some embodiments, the preheating temperature of the preheater 32 can be 50° C.

In some embodiments, as shown in FIG. 2, the vaporization system also comprises a pressurization pipeline 8. The gas inlet of the pressurization pipeline 8 is communicated with the gas source. The gas outlet end of the pressurization pipeline 8 is communicated with the liquid source bottle 31. The entrance of the gas inlet pipeline 5 is communicated with the liquid source bottle 31. The gas outlet end of the pressurization pipeline 8 can be higher than the internal liquid surface of the liquid source bottle 31. The entrance of the gas inlet pipeline 5 is lower than the internal liquid surface of the liquid source bottle 31. Thus, the introduced carrier gas can remain in the hollow chamber above the liquid surface. As the carrier gas is introduced, the pressure in the hollow chamber above the liquid surface can gradually rise to pump the process liquid back into the gas inlet pipeline 5. A third on/off valve 81 and a second check valve 82 can be arranged on the pressurization pipeline 8. The third on/off valve 81 can be configured to control the pressurization pipeline 8 to be on/off. The second check valve 82 can be arranged downstream of the third on/off valve 81 and can be configured to prevent the gas in the liquid source bottle 31 from entering back into the pressurization pipeline 8.

In some embodiments, a pressure detector 83 can be also arranged inside the pressurization pipeline 8 to detect the internal pressure of the pressurization pipeline 8. Since the pressurization pipeline 8 is communicated with the upper hollow chamber of the liquid source bottle 31, the internal gas pressure of the pressurization pipeline 8 can reflect the internal gas pressure in the upper hollow chamber of the liquid source bottle 31. The process liquid source 3 can also include a pressure relief pipeline 33. The gas inlet end of the pressure relief pipeline 33 can communicate with the liquid source bottle 31. The gas outlet end can be configured to communicate with the vent. The fifth on/off valve 331 can be arranged on the pressure relief pipeline 33. The fifth on/off valve 331 can be configured to control the on/off of the pressure relief pipeline 33 according to the pressure detected by the pressure detector 83. In some embodiments, when the internal gas pressure of the pressurization pipeline 8 is detected to reach the preset maximal pressure, the pressure relief pipeline 33 arranged at the pressurization pipeline 8 or communicating with the liquid source bottle 31 can be opened to relieve the pressure until the internal gas pressure in the pressurization pipeline 8 reaches the preset minimum gas pressure to prevent the internal gas pressure of the liquid source bottle 31 from being excessively large. In some embodiments, the preset minimum gas pressure and the preset maximum gas pressure can range from 0.3 bar to 0.7 bar.

In some embodiments, the process liquid source 3 can include a liquid level controller, a first liquid level sensor (LS1) 311, a second liquid level sensor (LS2) 312, and a refilling pipeline 313. The first liquid level sensor 311 and the second liquid level sensor 312 can be arranged inside the liquid source bottle 31 and between the gas outlet of the pressurization pipeline 8 and the gas inlet of the gas inlet pipeline 5. The position of the first liquid level sensor 311 can be higher than the position of the second liquid level sensor 312. The first liquid level sensor 311 and the second liquid level sensor 312 can be configured to monitor the height of the internal liquid surface of the source bottle 31 and send the height of the liquid surface to the liquid level controller. By setting the height of the first liquid level sensor 311 to be higher than the position of the second liquid level sensor 312, different heights of the liquid surface can be monitored. In some embodiments, the first liquid level sensor 311 and the second liquid level sensor 312 can send the detection value to the liquid level controller in real-time to monitor the liquid level in real-time. In some embodiments, taking the first liquid level sensor 311 and the second liquid level sensor 312 shown in FIG. 2 as an example, if the first liquid level sensor 311 and the second liquid level sensor 312 can be sensors at two positions corresponding to the preset highest liquid surface and the preset lowest liquid surface. Embodiments of the present disclosure are not limited to this. The first liquid level sensor 311 and the second liquid level sensor 312 can be replaced by single distance sensors.

The refilling pipeline 313 can communicate with the liquid source bottle 31. In some embodiments, the liquid inlet of the refilling pipeline 313 can be configured to communicate with the liquid source (e.g., DIW) for providing the process liquid. The liquid outlet can communicate with the liquid source bottle 31 to transfer the process liquid to the liquid source bottle 31. The refilling pipeline 313 can include a fourth on/off valve 3131. The fourth on/off valve 3131 can be configured to control the on and off of the refilling pipeline 313. The liquid level controller can be configured to control the fourth on/off valve 3131 to open or close according to the liquid surface height sent by the first liquid level sensor 311 and the second liquid level sensor 312 to refill the liquid in the liquid source bottle 31.

The vaporization system in embodiments of the present disclosure is not limited to only supplying steam to one process chamber and can be further suitable to supply steam to a plurality of process chambers. In some embodiments, as another technical solution, embodiments of the present disclosure further provide semiconductor process equipment, including a process chamber and the vaporization system. One or more process chambers can be included. The number of the gas outlet pipelines can be same as the number of process chambers, and the outlet ends of the gas outlet pipelines can communicate with the process chambers in a one-to-one correspondence.

In some embodiments, the vaporization system can further include a central control unit. The central control unit can be configured to detect a process chamber that waits to perform processing from the plurality of process chambers, and the gas outlet pipeline can be correspondingly controlled to open. The central control unit can be further configured to control the liquid flow rate controller to adjust the process liquid flow rate according to the steam flow rate actually required by the process chamber that waits to perform the processing and control the gas flow rate, i.e., the carrier gas flow rate. Thus, the steam can be simultaneously transferred to the plurality of different process chambers.

Moreover, the central control unit can be further configured to control the high-temperature flow rate controller in the corresponding gas outlet pipeline to adjust the steam flow rate according to the actual required steam flow rate of the process chamber that waits to perform the processing to transfer the steam simultaneously to the plurality of different process chambers with the corresponding flow rate.

In some embodiments, the central control unit can be further configured to send a control signal to a lower-level machine such as the liquid level controller and the temperature controller to realize the automatic control of the vaporization system.

The vaporization system of embodiments of the present disclosure can include the jet mixer, the liquid inlet pipeline configured to transfer the process liquid to the jet mixer, and the gas inlet pipeline configured to transfer the carrier gas to the jet mixer. Thus, the jet mixer can be configured to mix the process liquid and the carrier gas transferred into the jet mixer to form the mist-like mixture. The vaporization system can further include the mixing heater connected to the outlet of the jet mixer. The mixing heater can be configured to heat the liquid transferred into the mixing heater to heat the mist-like mixture to vaporize into steam using the mixing heater. Thus, the process liquid output by the process liquid source can be sufficiently vaporized to cause the process gas amount in the formed steam to be the process liquid amount output by the liquid inlet pipeline. Thus, the amount of the process gas participating in the process reaction in the processing chamber can be controllable to further improve the effectiveness and uniformity of the process.

It can be noted that the above embodiments are merely exemplary embodiments for illustrating the principle of the present disclosure. However, the present disclosure is not limited to this. For those ordinary skills in the art, various modifications and improvements can be made without departing from the spirit and essence of the present disclosure. These modifications and improvements can be within the scope of the present disclosure.

1. A vaporization system, configured to transfer steam to a process chamber, comprising a jet mixer, a mixing heater, a process liquid source, a gas inlet pipeline, a liquid inlet pipeline, and a gas outlet pipeline, wherein:
the process liquid source is configured to store or output a process liquid;
a first inlet of the jet mixer is communicated with a gas source through the gas inlet pipeline, a second inlet of the jet mixer is communicated with a process liquid source through the liquid inlet pipeline, the jet mixer is configured to mix the carrier gas input from the gas source with the process liquid input from the process liquid source to form a mist-like mixture; and
an inlet of the mixing heater is communicated with an outlet of the jet mixer, the mixing heater is configured to heat the mist-like mixture to vaporize the mist-like mixture into the steam, and an outlet of the mixing heater is communicated with the process chamber through the gas outlet pipeline.

2. The vaporization system according to claim 1, wherein:
a gas flow rate controller is arranged on the gas inlet pipeline and is configured to control a flow rate of the carrier gas transferred to the jet mixer through the gas inlet pipeline; and
a liquid flow rate controller is arranged on the liquid inlet pipeline and is configured to control a flow rate of the process liquid transferred to the jet mixer through the liquid inlet pipeline.

3. The vaporization system according to claim 2, wherein:
a first on/off valve and a first check valve are further arranged on the gas inlet pipeline, the first on/off valve is located upstream of the gas flow rate controller and is configured to control the gas inlet pipeline to be on or off, and the first check valve is located downstream of the gas flow controller and is configured to prevent the mist-like mixture in the jet mixer from backflowing into the gas inlet pipeline; and
a second on/off valve is further arranged on the liquid inlet pipeline, and the second on/off valve is located upstream of the liquid flow rate controller and is configured to control the liquid inlet pipeline to be on or off.

4. The vaporization system according to claim 1, wherein a high-temperature flow rate controller is arranged on the gas outlet pipeline and is configured to control the flow rate of the steam transferred to the process chamber.

5. The vaporization system according to claim 4, wherein the vaporization system further comprises a thermal insulation unit, and the thermal insulation unit is arranged on the gas outlet pipeline and the high-temperature flow rate controller and is configured to heat the gas outlet pipeline and the high-temperature flow rate controller.

6. The vaporization system according to claim 1, wherein the process liquid source comprises:
a liquid source bottle configured to store the process liquid; and
a preheater configured to heat the liquid source bottle so that the process liquid in the liquid source bottle is kept at a preset temperature.

7. The vaporization system according to claim 6, further comprising:
a pressurization pipeline, a gas inlet end of the pressurization pipeline communicating with the gas source, the gas outlet end of the pressurization pipeline communicating with the liquid source bottle, the inlet end of the liquid inlet pipeline communicating with the liquid source bottle, and the gas outlet end of the pressurization pipeline being higher than the inlet end of the liquid inlet pipeline, comprising:
a third on/off valve configured to control the pressurization pipeline to be on or off; and
a second check valve located downstream of the third on/off valve and configured to prevent gas in the liquid source bottle from backflowing into the pressurization pipeline.

8. The vaporization system according to claim 7, wherein the process liquid source further comprises a liquid level controller, a first liquid level sensor, a second liquid level sensor, and a liquid refilling pipeline, wherein:
the first liquid level sensor and the second liquid level sensor are arranged in the liquid source bottle and between a position of a gas outlet end of the pressurization pipeline and a position of an inlet end of the liquid inlet pipeline, the first liquid level sensor is arranged at a position higher than a position of the second liquid level sensor, the first liquid level sensor and the second liquid level sensor are configured to monitor a liquid surface height inside the liquid source bottle and send a detected liquid surface height value to the liquid level controller;
the liquid refilling pipeline is communicated with the liquid source bottle and is configured to transfer the process liquid to the liquid source bottle, and a fourth on/off valve is arranged on the liquid refilling pipeline and is configured to control the liquid refilling pipeline to be on or off, and
the liquid level controller is configured to control the fourth on/off valve to be on or off according to the liquid surface height value sent by the first liquid level sensor and the second liquid level sensor.

9. The vaporization system according to claim 7, wherein:
the pressurization pipeline further comprises a pressure detector configured to detect pressure inside the liquid source bottle; and
the process liquid source further comprises a pressure-releasing pipeline communicating with the liquid source bottle or the pressurization pipeline, a fifth on/off valve being arranged on the pressure-releasing pipeline and configured to control the on/off of the pressure-releasing pipeline to be on or off according to a pressure value detected by the pressure detector.

10. Semiconductor process equipment comprising:
a process chamber; and
a vaporization system, configured to transfer steam to the process chamber, comprising a jet mixer, a mixing heater, a process liquid source, a gas inlet pipeline, a liquid inlet pipeline, and a gas outlet pipeline, wherein:
the process liquid source is configured to store or output a process liquid;
a first inlet of the jet mixer is communicated with a gas source through the gas inlet pipeline, a second inlet of the jet mixer is communicated with a process liquid source through the liquid inlet pipeline, the jet mixer is configured to mix the carrier gas input from the gas source with the process liquid input from the process liquid source to form a mist-like mixture; and
an inlet of the mixing heater is communicated with an outlet of the jet mixer, the mixing heater is configured to heat the mist-like mixture to vaporize the mist-like mixture into the steam, and an outlet of the mixing heater is communicated with the process chamber through the gas outlet pipeline;
wherein one or more process chambers are included, a number of the gas outlet pipelines is same as a number of process chambers, and outlet ends of the gas outlet pipelines communicate with the process chambers in a one-to-one correspondence.

11. The semiconductor process equipment according to claim 10, wherein:
a gas flow rate controller is arranged on the gas inlet pipeline and is configured to control a flow rate of the carrier gas transferred to the jet mixer through the gas inlet pipeline; and
a liquid flow rate controller is arranged on the liquid inlet pipeline and is configured to control a flow rate of the process liquid transferred to the jet mixer through the liquid inlet pipeline.

12. The semiconductor process equipment according to claim 11, wherein:
a first on/off valve and a first check valve are further arranged on the gas inlet pipeline, the first on/off valve is located upstream of the gas flow rate controller and is configured to control the gas inlet pipeline to be on or off, and the first check valve is located downstream of the gas flow controller and is configured to prevent the mist-like mixture in the jet mixer from backflowing into the gas inlet pipeline; and
a second on/off valve is further arranged on the liquid inlet pipeline, and the second on/off valve is located upstream of the liquid flow rate controller and is configured to control the liquid inlet pipeline to be on or off.

13. The semiconductor process equipment according to claim 10, wherein a high-temperature flow rate controller is arranged on the gas outlet pipeline and is configured to control the flow rate of the steam transferred to the process chamber.

14. The semiconductor process equipment according to claim 13, wherein the vaporization system further comprises a thermal insulation unit, and the thermal insulation unit is arranged on the gas outlet pipeline and the high-temperature flow rate controller and is configured to heat the gas outlet pipeline and the high-temperature flow rate controller.

15. The semiconductor process equipment according to claim 10, wherein the process liquid source comprises:
a liquid source bottle configured to store the process liquid; and
a preheater configured to heat the liquid source bottle so that the process liquid in the liquid source bottle is kept at a preset temperature.

16. The semiconductor process equipment according to claim 15, wherein the vaporization system further comprises:
a pressurization pipeline, a gas inlet end of the pressurization pipeline communicating with the gas source, the gas outlet end of the pressurization pipeline communicating with the liquid source bottle, the inlet end of the liquid inlet pipeline communicating with the liquid source bottle, and the gas outlet end of the pressurization pipeline being higher than the inlet end of the liquid inlet pipeline, comprising:
a third on/off valve configured to control the pressurization pipeline to be on or off; and
a second check valve located downstream of the third on/off valve and configured to prevent gas in the liquid source bottle from backflowing into the pressurization pipeline.

17. The semiconductor process equipment according to claim 16, wherein the process liquid source further comprises a liquid level controller, a first liquid level sensor, a second liquid level sensor, and a liquid refilling pipeline, wherein:
the first liquid level sensor and the second liquid level sensor are arranged in the liquid source bottle and between a position of a gas outlet end of the pressurization pipeline and a position of an inlet end of the liquid inlet pipeline, the first liquid level sensor is arranged at a position higher than a position of the second liquid level sensor, the first liquid level sensor and the second liquid level sensor are configured to monitor a liquid surface height inside the liquid source bottle and send a detected liquid surface height value to the liquid level controller;
the liquid refilling pipeline is communicated with the liquid source bottle and is configured to transfer the process liquid to the liquid source bottle, and a fourth on/off valve is arranged on the liquid refilling pipeline and is configured to control the liquid refilling pipeline to be on or off, and
the liquid level controller is configured to control the fourth on/off valve to be on or off according to the liquid surface height value sent by the first liquid level sensor and the second liquid level sensor.

18. The semiconductor process equipment according to claim 16, wherein:
the pressurization pipeline further comprises a pressure detector configured to detect pressure inside the liquid source bottle; and
the process liquid source further comprises a pressure-releasing pipeline communicating with the liquid source bottle or the pressurization pipeline, a fifth on/off valve being arranged on the pressure-releasing pipeline and configured to control the on/off of the pressure-releasing pipeline to be on or off according to a pressure value detected by the pressure detector.
